(19) United States
(12) Patent Application Publication
(10) Pub. No.: US 2007/0007636 A1
(43) Pub. Date: Jan. 11, 2007

(54) Parallel chip embedded printed circuit board and manufacturing method thereof

(75) Inventors: Jin-Yong Ahn, Suwon-si (KR); Chang Sup Ryu, Daejeon (KR); Suk-Hyeon Cho, Suwon-si (KR); Joon Sung Kim, Seoul (KR); Han Seo Cho, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/474,974

(22) Filed: Jun. 27, 2006

(30) Foreign Application Priority Data
Jun. 30, 2005 (KR) 10-2005-0057993
Sep. 27, 2005 (KR) 10-2005-0089685

(51) Int. Cl. H01L 23/02; H01L 21/00

(52) U.S. Cl. 257/679; 438/121; 257/E23.064

(57) ABSTRACT

A parallel chip embedded printed circuit board and manufacturing method thereof are disclosed. With a method of manufacturing a parallel chip embedded printed circuit board, comprising: (a) forming a parallel chip by connecting in parallel a plurality of unit chips having electrodes or electrically connected members formed on the upper and lower surfaces thereof, using at least one conductive member; (b) joining an electrode on one side of the parallel chip to a first board; and (c) joining an electrode on the other side of the parallel chip to a second board, chips may be embedded in a printed circuit board at a low cost, as a plurality of unit chips can be embedded at once, and a mechanical drill or router can be used instead of a laser drill in perforating the cavity or via holes.

### CROSS-REFERENCE TO RELATED APPLICATIONS

This application claims the benefit of Korean Patent Application No. 2005-57993 filed with the Korean Intellectual Property Office on Jun. 30, 2005, and Korean Patent Application No. 2005-89685 filed with the Korea Industrial Property Office on Sep. 27, 2005, both of which are incorporated herein by reference in their entirety.

### BACKGROUND

1. Technical Field

The present invention relates to a printed circuit board, and in particular, to a parallel chip embedded printed circuit board and manufacturing method thereof.

2. Description of the Related Art

As electric circuits become more densified and highly integrated, there is an increasing lack of space for passive components mounted on the board. To resolve this problem, the trend is towards an increasing number of components embedded within the board. Methods of forming passive elements within a board include using the substrate material as is while using copper (Cu) wiring, inserting polymer sheets, and forming thin film dielectrics, etc.

In prior art, the method was mainly used of manufacturing common passive components to have a thin form. However, the conventional embedding method may incur the following problems.

First, the passive components must be made thin in order for these to be embedded within the board. Making the passive components thin, which are typically made of ceramic materials, increases the risk of chipping and cracks ((a) of FIG. 1).

Second, in order to connect the terminals with the outside after a passive component with coated external electrodes are inserted within the board, via holes must be formed using a laser. This causes a rise in costs, and in the case of embedding small chips, the size of the chips may be smaller than the tolerance of the laser drill, to render the connection through via holes impossible ((b) of FIG. 1).

Third, when bending occurs during the manufacture or handling processes of the board, there is a risk that of the inner condenser breaking ((c) of FIG. 1).

Fourth, since the implemented capacity of a chip for embedding is typically 100 nF or less, it is impossible to embed high-capacity chips of 100 nF or more.

Fifth, a cavity must be formed in order to embed a chip within a board, and to insert several chips, the same number of cavities as that of the chips must be formed, resulting in increased processing costs. Also, since two via holes are required for one embedded chip, if for example there are about 1000 modules in a panel with 60 chips embedded in one module, a total of 120,000 via holes must be formed. This imposes a substantial increases in processing costs and manufacturing time.

Sixth, when the tolerances are great for the thickness of the chips, it is impossible to form laser via holes, and when the ratio of the width to the depth of a via hole is greater than 1:1, the lamination is not properly formed.

Prior art related to embedding chips in a printed circuit board includes, first, the method of connecting the condensers on embedded chips with external electrodes by means of laser via holes, which entails the problems of increased manufacturing cost and time, etc., and second, the technique of forming a single element by connecting two or more capacitors in parallel, which entails the limit that there are no specific technique disclosed for embedding parallel connected chips within a board.

### SUMMARY

The present invention aims to provide a parallel chip embedded printed circuit board and manufacturing method thereof, with which the mechanical strength of the thin chips embedded within the printed circuit board may be improved, a high capacity is enabled, the position tolerances may be evened out for the embedded chips and the external circuits, improper lamination may be avoided at the via holes, and the processing may be performed at a low cost.

Additional aspects and advantages of the present invention will be set forth in part in the description which follows and, in part, will be obvious from the description, or may be learned by practice of the invention.

One aspect of the present invention provides a method of manufacturing a parallel chip embedded printed circuit board comprising: (a) forming a parallel chip by connecting in parallel a plurality of unit chips having electrodes or electrically connected members formed on the upper and lower surfaces thereof, using at least one conductive member; (b) joining an electrode on one side of the parallel chip to a first board; and (c) joining an electrode on the other side of the parallel chip to a second board.

Also, a method of manufacturing a parallel chip embedded printed circuit board is provided, comprising: (d) forming a parallel chip by mounting a plurality of unit chips. on at least one conductive member joined to a first board; (e) stacking a third board, having at least one cavity perforated in correspondence with the position of the plurality of unit chips, onto the first board; and (f) stacking a second board onto the third board, and electrically connecting the plurality of unit chips with external circuits.

Operation (a) or operation (b) may further comprise forming a third board having at least one cavity perforated in correspondence with the size of the parallel chip, and preferably, the method may further comprise stacking the third board onto the first board to insert the parallel chip in the cavity, between operation (b) and operation (c).

The conductive member may be any one or more of conductive pastes, conductive polymer films, conductive polymers, bidirectional conductive tapes, and conductive epoxys. The third board may be a copper clad laminate (CCL) with circuits formed thereon. The circuits formed on the third board may preferably be electrically connected with the parallel chip.

Preferably, the cavity may be perforated using a mechanical drill or a router.

Any one of operations (a) to (c) may further comprise forming one or more via holes in the portion of the first board or the second board where the parallel chip is joined and filling the via holes with conductive paste. It may be preferable that each of the via holes be formed in a position corresponding to the plurality of unit chips.

The method may further comprise electrically connecting the plurality of unit chips and the conductive paste by pressing the first board or the second board towards the parallel chip.

Any one of operations (d) to (f) may further comprise forming one or more via holes in the portion of the first board where the conductive member is joined or in the portion of the second board where the plurality of unit chips are joined and filling the via holes with conductive paste.

The methods may further comprise, after the last operation, adding at least one bumped copper foil having a plurality of protrusions from the exterior of the first board or the second board, and electrically connecting the plurality of unit chips and the bumped copper foil by pressing the bumped copper foil towards the plurality of unit chips. Preferably, the plurality of protrusions may each be formed in a position corresponding to the plurality of unit chips.

It may be preferable that electrodes be formed on the left and right sides of the unit chip, and members electrically connected to the electrodes respectively be joined respectively to the upper and lower surfaces of the unit chip.

Also provided is a printed circuit board with an embedded parallel chip comprising a plurality of unit chips having electrodes or electrically connected members formed on the upper and lower surfaces thereof, a first conductive member electrically connecting the upper surfaces of the plurality of unit chips, and a second conductive member electrically connecting the lower surfaces of the plurality of unit chips.

Preferably, the first conductive member may be joined to a first board, and the second conductive member may be joined to a second board. It may be preferable for a third board having a cavity perforated in correspondence with the size of the parallel chip to be positioned between the first board and the second board, and for the parallel chip to be inserted into the cavity.

The third board may be a copper clad laminate (CCL) with circuits formed thereon, and the circuits may be electrically connected with the parallel chip. Preferably, one or more via holes may be formed in the portion of the first board or the second board where the parallel chip is joined, and the via holes may be filled with conductive paste. It may be preferable that the via holes each be formed in a position corresponding to the plurality of unit chips.

Preferably, at least one bumped copper foil having a plurality of protrusions may be joined to the exterior of the first board or the second board, and the plurality of protrusions may be inserted into the first board or the second board. Each of the plurality of protrusions may preferably be formed in a position corresponding to the plurality of unit chips.

The first conductive member and the second conductive member may be any one or more of conductive paste, conductive polymer films, conductive polymers, bidirectional conductive tape, and conductive epoxy.

### BRIEF DESCRIPTION OF THE DRAWINGS

These and/or other aspects and advantages of the present invention will become apparent and more readily appreciated from the following description of the embodiments, taken in conjunction with the accompanying drawings of which:

FIG. 1 shows schematic views illustrating problems in embedding techniques of prior art.

FIG. 2 shows schematic views of the composition of a parallel chip according to a preferred embodiment of the present invention.

FIG. 3 shows schematic views of a chip in which electrodes are formed in an up/down configuration according to a preferred embodiment of the present invention.

FIG. 4 shows a schematic diagram illustrating a method of forming a cavity in a third board according to a preferred embodiment of the present invention.

FIG. 5 shows a schematic diagram illustrating a method of forming via holes in the first or second board according to a preferred embodiment of the present invention.

FIG. 6 shows a flowchart illustrating a method of manufacturing a parallel chip embedded printed circuit board according to a preferred embodiment of the present invention.

FIG. 7 shows a schematic diagram illustrating a method of manufacturing a parallel chip embedded printed circuit board according to a preferred embodiment of the present invention.

FIG. 8 shows a cross-sectional view of a parallel chip embedded printed circuit board according to another preferred embodiment of the present invention.

FIG. 9 shows a cross-sectional view of a parallel chip embedded printed circuit board according to another preferred embodiment of the present invention..

FIG. 10 shows cross-sectional views of a parallel chip embedded printed circuit board according to another preferred embodiment of the present invention.

FIG. 11 shows a cross-sectional view of a parallel chip embedded printed circuit board according to another preferred embodiment of the present invention.

FIG. 12 shows a cross-sectional view of a parallel chip embedded printed circuit board according to another preferred embodiment of the present invention.

FIG. 13 shows a cross-sectional view of a parallel chip embedded printed circuit board according to another preferred embodiment of the present invention.

FIG. 14 shows a cross-sectional view of a parallel chip embedded printed circuit board according to another preferred embodiment of the present invention.

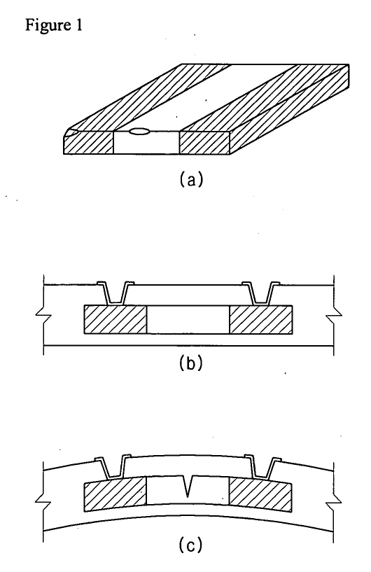

### DETAILED DESCRIPTION

Reference will now be made in detail to the embodiments of the present invention, examples of which are illustrated in the accompanying drawings, wherein like reference numerals refer to the like elements throughout. The embodiments are described below in order to explain the present invention by referring to the figures.

Aspects of the present invention provide a technique of embedding thin chips at a low cost, the main features of which are described below.

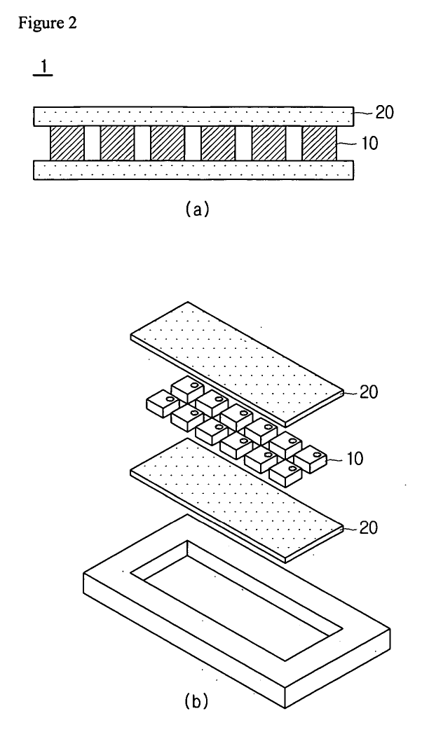

FIG. 2 shows schematic views of the composition of a parallel chip according to a preferred embodiment of the present invention. In FIG. 2 are illustrated unit chips 10 and conductive members 20. In order to prevent cracks or damage on the chip even when a bending force is applied to the board in which the chip is embedded, embodiments of the present invention employ embedding a plurality of unit chips 10 connected in parallel using conductive members 20, instead of embedding a single high-capacity chip.

In prior art, the size of the chips to be embedded may be smaller than the tolerance of the laser drill, to render the electrical connection through via holes impossible. Embodiments of the present invention, however, allow electrical connection regardless of the size of the unit chips 10, since they employ connecting several small chips 10 in parallel to form a single parallel chip.

Thus, by forming a parallel chip using conductive members 20, the thickness tolerances of the plurality of unit chips 10 may be evened out, and as widths of the laser via holes may be kept sufficiently larger than the depths, the problem of improper lamination may also be resolved.

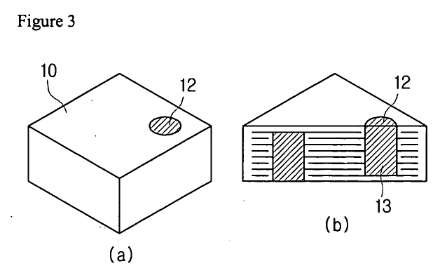

FIG. 3 shows schematic views of a chip in which electrodes are formed in an up/down configuration according to a preferred embodiment of the present invention. In FIG. 3 are illustrated a unit chip 10, electrodes 12, and via holes 13. The electrodes of the chip embedded in embodiments of the present invention are of the up/down configuration, and not the left/right configuration. To separate the electrodes in an up/down configuration, the internal electrode layers are interconnected through via holes 13, and the electrodes 12 having different polarities are formed respectively on the upper and lower sides.

However, the unit chip having electrodes of an up/down configuration used to compose a parallel chip according to aspects of the present invention may not necessarily be formed in the manner set forth above, and may be formed in any other manner that results in electrodes formed respectively on the upper and lower surfaces.

To compose a parallel chip such as that shown in FIG. 2 using a unit chip such as that shown in FIG. 3, each of the electrodes on the upper and lower surfaces of a plurality of unit chips 10 are connected electrically. The electrical connection between each electrode is accomplished using conductive members 20, preferably conductive polymer films, conductive polymers, bidirectional conductive tapes, and conductive epoxys, etc.

By arranging the unit chips 10 on the conductive members 20, cutting to form a parallel chip, and afterwards inserting into the board, chips of a high capacity may be embedded within the board. Also, by joining the conductive members 20 onto the upper and lower surfaces of the unit chips, the conductive members 20 even out the thickness tolerances of the plurality of unit chips, and also the mechanical strength of the parallel chip is improved by the conductive members 20 joined to the upper and lower surfaces.

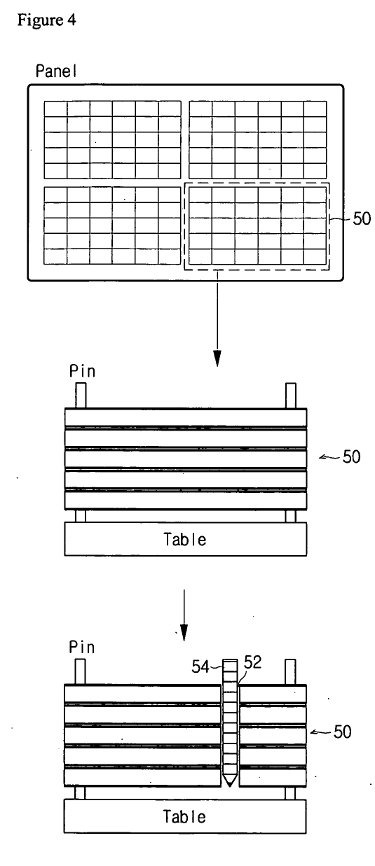

FIG. 4 shows a schematic diagram illustrating a method of forming a cavity in a third board according to a preferred embodiment of the present invention. In FIG. 4 are illustrated a board 50, a cavity 52, and a drill 54. To embed a parallel chip within a printed circuit board according to an embodiment of the present invention, the cavity 52 is formed in a portion of the board 50 where the parallel chip is to be embedded, and the boards are stacked so that the parallel chip is inserted into the cavity 52.

The cavity 52 according to an embodiment of the invention may be formed using a mechanical drill or a router. Thus, costs may be reduced by a significant amount, compared to the prior method of using a laser for the electrical connection between the chips and external circuits.

That is, when using a single parallel chip by connecting several or several tens of the plurality of unit chips, the unit chips and external circuits may be electrically connected with a single round of drilling instead of the several or several tens of rounds of laser drilling. Further, as the dimensions for the drilling correspond to several or several tens times the dimensions of a unit chip, the cavity 52 may satisfactorily be formed with drilling of a much lower degree of precision.

Thus, as the process that relied on laser drilling in prior art may be implemented using a mechanical drill or router 54, the costs related to laser processing may be reduced. Moreover, as illustrated in FIG. 4, the mechanical drill or router 54 may be used to process several boards at once, to increase the reduction in costs. That is, a plurality of chips may be embedded at once, without processing in the same number of rounds as the number of embedded chips, so that the processing may be performed at a low cost.

However, the present invention is not limited to the case of using the mechanical drill or router for forming the cavity, and it is to be appreciated that other types of perforation tools may be used that forms the cavity in the required degree of precision.

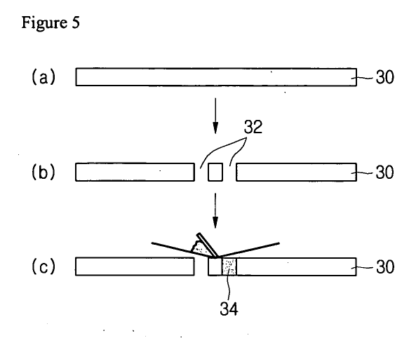

FIG. 5 shows a schematic diagram illustrating a method of forming via holes in the first or second board according to a preferred embodiment of the present invention. In FIG. 5 are illustrated a board 30, via holes 32, and conductive paste 34.

To reduce costs, in embodiments of the present invention, the electrical connection between the embedded chips and external circuits does not rely on laser via holes, and instead, via holes 32 are perforated in the board 30 and filled with conductive paste 34 to form electrical connection paths between the external circuits and embedded chips. As the via holes 32 are electrical connection paths for a parallel chip in which a plurality of unit chips are connected, it is apparent that they may be perforated with a sufficient degree of precision with a mechanical drill, instead of a laser drill.

Also, the via holes 32 may be processed at once by superposing several layers of boards, as shown in the cavity of FIG. 4. The fact that a mechanical drill may be used and the fact that several layers may be processed at once provide the effect of cost reduction characteristic to embodiments of the invention.

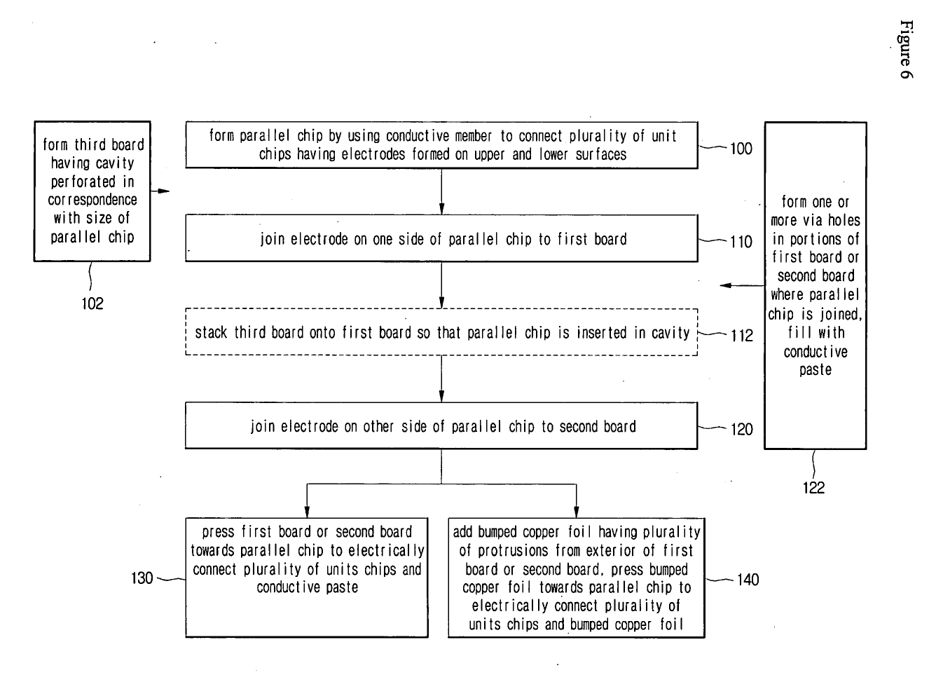

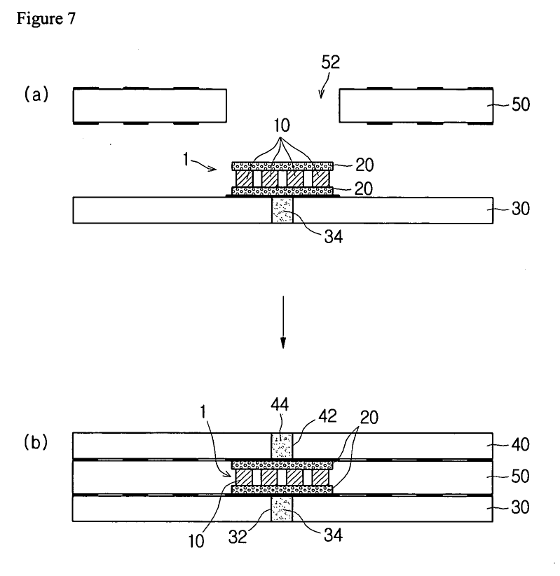

FIG. 6 shows a flowchart illustrating a method of manufacturing a parallel chip embedded printed circuit board according to a preferred embodiment of the present invention, and FIG. 7 shows a schematic diagram illustrating a method of manufacturing a parallel chip embedded printed circuit board according to a preferred embodiment of the present invention. In FIG. 7 are illustrated a parallel chip 1, unit chips 10, conductive members 20, a first board 30, a second board 40, via holes 32, 42, conductive paste 34, 44, a third board 50, and a cavity 52.

Embodiments of the invention connect the plurality of unit chips 10 in parallel to form the thin high-capacity parallel chip 1 which is embedded in the printed circuit board, to not only resolve the problems related to the mechanical strength and capacity limit of the embedded chips, but also to provide low costs by using a mechanical drill or router, etc., in processing operations previously performed by laser drilling. After forming the parallel chip 1, the basic mode is to embed it after positioning it between the first board 30 and the second board 40.

In other words, the plurality of unit chips 10 of an up/down configuration having electrodes formed on the upper and lower surfaces are connected in parallel using conductive members 20 to form a parallel chip (operation 100). Here, the conductive members 20 may be any one of conductive polymer films, conductive polymers, bidirectional conductive tape, and conductive epoxy, or a combination thereof.

The conductive members in embodiments of the invention not only connect the plurality of unit chips 10 in parallel, but also augment the mechanical strength of the parallel chip 1 to resolve the problem of breakage, etc., of thin chips used in prior embedding techniques, and in addition even out the thickness tolerances of the plurality of unit chips for easier embedding of the parallel chip.

Further, as will be described below, when those conductive members are used that contain conductive matter in a paste, electrical connection is implemented by applying pressure, so that after embedding a parallel chip, electrical connection may be obtained between each of the individual unit chips and the external circuits.

Next, the electrode on one side of the parallel chip 1, formed by connecting the plurality of unit chips 10, is joined to the first board 30 (operation 110), and the electrode of the other side is joined to the second board 40 (operation 120). That is, the parallel chip 1 is positioned in-between and embedded within the printed circuit board.

Here, it is preferable that a third board 50 of a thickness corresponding to the height of the parallel chip 1 be positioned between the first board 30 and the second board 40. It may be desirable to form a cavity 52 on the third board 50 to house the parallel chip 1 in the cavity 52 when it is placed between the first board 30 and the second board 40.

That is, during the operation of forming the parallel chip 1 or the operation of joining the parallel chip 1 to the first board 30, a third board 50 may separately be formed in which a cavity 52 is perforated in correspondence with the size of the parallel chip 1 (operation 102), and after the parallel chip 1 is joined to the first board 30, the third board 50 may be stacked (operation 112) and the second board 40 may be stacked above it, by which the embedding of the parallel chip is completed.

The third board 50 may be a copper clad laminate (CCL) with circuits formed on one or either side. In this case, circuits formed on the third board 50 and electrodes of the parallel chip 1 may be electrically connected or insulated as necessary.

The cavity 52 formed on the third board 50 corresponds to the space where the parallel chip 1 is housed, and since the parallel chip 1 is a connection of a plurality of unit chips 10, its size may be several to several tens times the size of a unit chip 10. Therefore, the cavity 52 may preferably be perforated not by a laser drill as in prior art but by a mechanical drill or router. This difference in processing method may provide ease of manufacture and reduction in costs as benefits of the present invention.

In forming a parallel chip 1 to position between the first board 30 and the second board 40, it may be desirable to form one or more via holes 32, 42 on the first board 30 or the second board 40 and to fill the via holes with conductive paste 34, 44 (operation 122). Since the via holes 32, 42 are paths for electrically connecting the external circuits and the parallel chip 1, they are formed in the portions where the parallel chip 1 is joined, and for convenience in the perforation and filling processes, they may preferable be formed before the parallel chip 1 is joined.

Of course, the perforation of the via holes 32, 42 and the filling of the conductive paste 34, 44 according to embodiments of the invention does not necessarily have to be performed before the parallel chip 1 is joined, and it is to be appreciated that these may be performed after the parallel chip 1 is joined, as long as the electrical connection may be implemented between the parallel chip 1 and external circuits formed on the first board 30 or the second board 40.

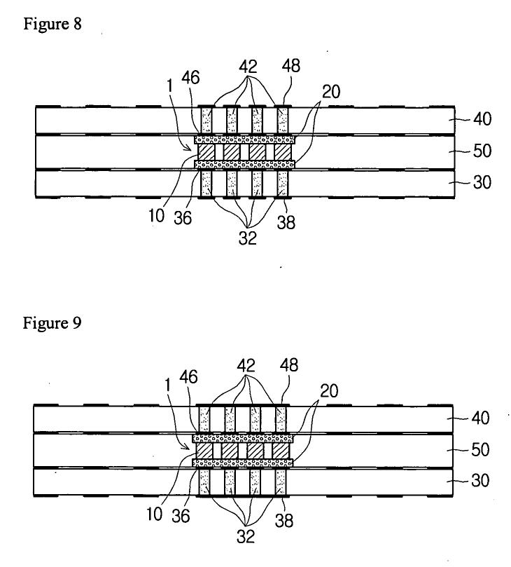

FIG. 8 shows a cross-sectional view of a parallel chip embedded printed circuit board according to another preferred embodiment of the present invention. In FIG. 8 are illustrated a parallel chip 1, unit chips 10, conductive members 20, a first board 30, a second board 40, a third board 50, via holes 32, 42, internal circuits 36, 46, and external circuits 38, 48.

In another embodiment of the present invention, a plurality of via holes 32, 42 are perforated on the first board 30 or the second board 40 for separate electrical connections between the plurality of unit chips 10 used to form the parallel chip 1 and the external circuits 38, 48. Thus, it is desirable to form the plurality of via holes 32, 42 in positions corresponding to the plurality of unit chips 10. Also, as illustrated in FIG. 8, the external circuits 38, 48 are formed in correspondence with the positions of the plurality of via holes 32, 42.

Of course, since the conductive members 20 are conductive, the composition of FIG. 8 in itself does not allow separate electrical connections between each of the unit chips 10 and the external circuits 38, 48, but when using conductive members containing conductive matter in a paste, since the electrical connection is implemented by applying pressure, the electrical connection may be implemented between each unit chip 10 and an external circuit 38, 48, after embedding the parallel chip 1.

In other words, although the conductive members 20 are not conductive in a composition such as that shown in FIG. 8, when the first board 30 or the second board 40 is pressed towards the parallel chip 1, pressure is applied on the conductive paste, so that the conductive matter contained within is compressed, whereby conduction is obtained.

When conductive members (bidirectional conductive films) are also used where conduction is obtained by applying pressure in a composition such as that shown in FIG. 7, since the via holes are not formed in correspondence to each unit chip 10, the amount of force per unit area is less compared to a composition such as that of FIG. 8, so there is a possibility that the electrical connection by applying pressure may not be implemented. Also, since the unit chips are electrically connected to an external circuits through one via hole, there is no substantial value to forming an electrical connecting by means of applying pressure.

Therefore, for separate electrical connections between each of the unit chips 10 and the external circuits 38, 48, it is preferable for the via holes 32, 42 to be formed in positions corresponding to each of the unit chips 10 and filled with conductive paste 34, 44, after which pressure will be applied on the first board 30 or the second board 40 (operation 130 of FIG. 6). Also, as illustrated in FIG. 8, it is apparent that the internal circuits 36, 46 and external circuits 38, 48 be formed in correspondence with each of the unit chips 10 and via holes 32, 42.

FIG. 9 shows a cross-sectional view of a parallel chip embedded printed circuit board according to another preferred embodiment of the present invention.. In FIG. 9 are illustrated a parallel chip 1, unit chips 10, conductive members 20, a first board 30, a second board 40, a third board 50, via holes 32, 42, internal circuits 36, 46, and external circuits 38, 48.

Even when using conductive members where conduction is obtained by applying pressure, as in the embodiment illustrated in FIG. 8, there may be occasions where a parallel chip 1 and external circuits 38, 48 are connected without the need to connect each of the unit chips 10 and the external circuits 38, 48. In such a case, besides the method of forming one via hole as in FIG. 7, via holes may be formed in positions corresponding to each of the unit chips, and pressure may be applied on the first board 30 or the second board 40 to implement electrical connections between the unit chips 10 and the external circuits 38, 48, while single external circuits 38, 48 may be formed without corresponding to each of the unit chips.

Since the force applied per unit chip during the pressing is greater than that in the case of FIG. 7, the possibility of an electrical connection implemented by applying pressure is improved.

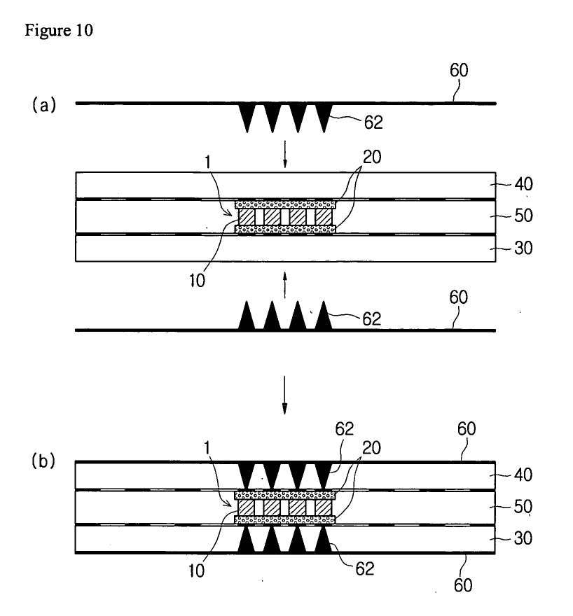

FIG. 10 shows cross-sectional views of a parallel chip embedded printed circuit board according to another preferred embodiment of the present invention. In FIG. 10 are illustrated a parallel chip 1, unit chips 10, conductive members 20, a first board 30, a second board 40, a third board 50, bumped copper foils 60, and protrusions 62.

The present embodiment is characterized in that, after the parallel chip 1 is positioned between the first board 30 and the second board 40 and embedded, the bumped copper foils 60 each having a plurality of protrusions 62 are pressed from the exterior of the first board 30 of the second board 40 towards the parallel chip 1 so that the plurality of unit chips 10 and the bumped copper foils 60 are electrically connected (operation 140 of FIG. 6).

The bumped copper foil having a plurality of protrusions 62 is an element known to those skilled in the art, and detailed explanations are omitted. In the present embodiment, bumped copper foils each having a plurality of protrusions 62 are used, whereby the processes are omitted of forming via holes 32, 42 on the first board 30 or the second board 40 for electrical connection between the embedded chip and the external circuits and of filling with conductive paste 34, 44, so that the chip embedded printed circuit board may be manufactured both quickly and with low costs.

It is to be appreciated that any kind of material known to those skilled in the art, that may be used for the first board 30 or the second board, such that the plurality of protrusions 62 protruding from the bumped copper foil 60 may be inserted into the first board 30 or the second board 40 to be connected to the conductive member 20, is included in the scope of the present invention.

Also, as in the descriptions of FIGS. 8 and 9, the plurality of protrusions 62 on the bumped copper foils 60 are preferably formed in positions corresponding to the plurality of unit chips 10 included in the parallel chip 1, in order for each of the unit chips 10 and the bumped copper foils 60 to be electrically connected.

Meanwhile, the printed circuit board produced by a method for manufacturing a parallel chip embedded printed circuit board according to embodiments of the invention, as illustrated in (b) of FIG. 7, FIG. 8, FIG. 9, and (b) of FIG. 10, is a printed circuit board in which a parallel chip 1 is embedded, where the parallel chip 1 comprises a first conductive member 20 electrically connecting the upper surface electrodes of a plurality of unit chips 10 having electrodes formed on the upper and lower surfaces thereof, and a second conductive member 20 electrically connecting the lower surface electrodes of the plurality of unit chips.

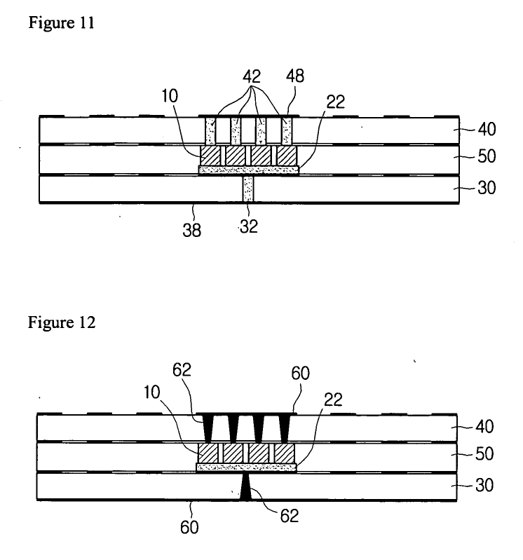

FIG. 11 shows a cross-sectional view of a parallel chip embedded printed circuit board according to another preferred embodiment of the present invention, and FIG. 12 shows a cross-sectional view of a parallel chip embedded printed circuit board according to another preferred embodiment of the present invention. In FIGS. 11 and 12 are illustrated unit chips 10, conductive paste 22, a first board 30, a second board 40, a third board 50, via holes 32, 42, external circuits 38, 48, bumped copper foils 60, and protrusions 62.

FIGS. 11 and 12 show different embodiments of the present invention, in which instead of forming a parallel chip and afterwards embedding in the board as in the previous embodiments, the plurality of unit chips 10 are made to form the parallel chip while being mounted on the board.

Thus, to manufacture a parallel chip embedded printed circuit board illustrated in FIG. 11 or 12, first the conductive paste 22 is coated as the conductive member on the first board 30, which is a CCL board. Then, using SMT equipment, the plurality of unit chips 10 are mounted on the portion coated with conductive paste 22 to form a parallel chip, in which the plurality of unit chips 10 are aligned in parallel.

The following processes are to dry the conductive paste 22 and to stack the insulation board, just as in the previous embodiments. That is, the third board 50, in which a cavity is perforated in correspondence with the positions of the plurality of unit chips 10, is stacked onto the first board 30, the second board 40 is stacked onto the third board 50, and afterwards the plurality of unit chips 10 are electrically connected with the external circuits to complete the printed circuit board.

The electrical connection between the unit chips 10 and the external circuits 38, 48, as in the previous embodiments, may be implemented by perforating via holes 32, 42 and filling with conductive paste, or by pressing bumped copper foils 60 having a plurality of protrusions 62.

In FIG. 11, the via holes 32, 42 are perforated in the portion of the first board 30 where the conductive paste 22 is coated and in the portion of the second board 40 joining with the plurality of unit chips 10, and are filled with conductive paste to electrically connect the unit chips 10 and the external circuits 38, 48.

In FIG. 12, bumped copper foils 60 are joined, that have one or more protrusions 62 in correspondence with the portion of the first board 30 where the conductive paste 22 is coated and with the portion of the second board 40 joining with the plurality of unit chips 10, and are pressed to electrically connect the unit chips 10 and the bumped copper foils 60, which are the external circuits 38, 48.

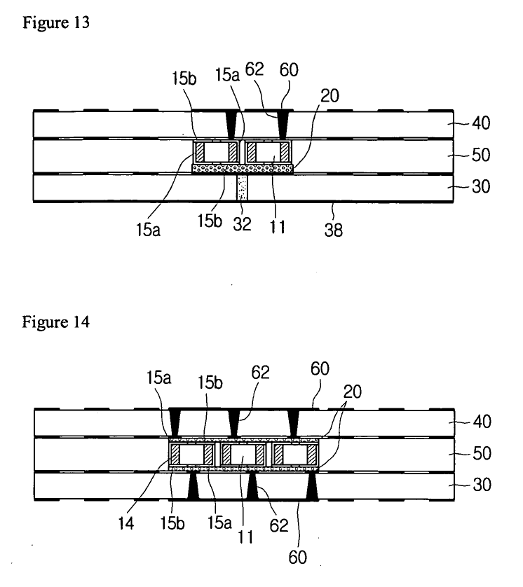

FIG. 13 shows a cross-sectional view of a parallel chip embedded printed circuit board according to another preferred embodiment of the present invention. In FIG. 13 are illustrated unit chips 11, electrodes 14, connection members 15a, 15b, a conductive member 20, a first board 30, a via hole 32, an external circuit 38, a second board 40, a third board 50, a bumped copper foil 60, and protrusions 62.

In the embodiment illustrated in FIG. 13, unlike those of FIGS. 11 and 12 with conductive paste 22 coating, after the conductive member 20 has been joined to the first board 30, the unit chips 11 are mounted to form a parallel chip.

That is, the conductive member 20 such as conductive tape is attached to a CCL board, which is the first board 30, and just as in FIGS. 11 and 12, the plurality of unit chips 11 are aligned in parallel by SMT to form a parallel chip.

Here, any chip may be used which has electrodes formed on the upper and lower surfaces or on the left and right surfaces. However, when using a chip with electrodes 14 formed on the left and right sides, the electrodes are joined with the connection members 15a, 15b, portions of which are positioned on the upper and lower surfaces of the chip, to implement a form equal to a chip having electrodes formed on the upper and lower surfaces.

In implementing a form equal to electrodes formed on the upper and lower surfaces of a chip using the connection members 15a, 15b, it is apparent to those skilled in the art that those connection members 15a, 15b must be used in which a portion 15a is made of a conductive matter, and the remaining portion is made of an insulating matter.

As in the previous embodiments, the following processes are to stack the third board 50 (the insulation board), and then to press the bumped copper foil 60 having a plurality of protrusions 62 so as to implement an electrical connection with the external circuit.

In the embodiments illustrated in FIGS. 11 to 13, conductive paste 22 is coated or conductive tape is attached on a CCL board, instead of using conductive films, or bidirectional conductive films, etc. as the conductive members 20, after which SMT equipment is used to align the chips in a parallel manner to form a parallel chip, and then electrical connection is implemented by forming via holes 32 on the first board 30 and the second board 40 and filling with conductive paste or by pressing bumped copper foils 60 on which are formed a plurality of protrusions 62.

FIG. 14 shows a cross-sectional view of a parallel chip embedded printed circuit board according to another preferred embodiment of the present invention. In FIG. 14 are illustrated unit chips 11, electrodes 14, connection members 15a, 15b, conductive members 20, a first board 30, a second board 40, a third board 50, bumped copper foils 60, and protrusions 62.

The embodiment illustrated in FIG. 14 represents the case where a printed circuit board with an embedded parallel chip is manufactured using units chips 11 such as typical MLCC's on which electrodes 14 are formed on the left and right sides.

Although the case with unit chips 11 having electrodes 14 formed on the left and right sides is similar to the case with unit chips 11 having electrodes formed on the upper and lower surfaces, since the electrodes of the chips are formed in different positions, a structure is formed that is equal to the case where the electrodes are formed on the upper and lower surfaces by joining the electrodes 14 to the connection members 15a, 15b.

After embedding the unit chips 11, the electrical connection with the external circuits, as described above, may be implemented by perforating via holes 32 on the first board 30 and the second board 40 and filling with conductive paste, or by pressing bumped copper foils 60 on which are formed a plurality of protrusions 62.

This embodiment may generally be used not only for MLCC's but also for embedding various kinds of chips, such as a resistor, and inductor, etc.

According to the present invention comprised as above, chips may be embedded in a printed circuit board at a low cost, as a plurality of unit chips can be embedded at once, and a mechanical drill or router can be used instead of a laser drill in perforating the cavity or via holes. Meanwhile, superior applicability is obtained, as the embedding may be performed in a variety of embodiments, to utilize a plurality of unit chips individually or as a single parallel chip.

Further, as a plurality of unit chips are parallel connected using conductive members, the tolerances from thickness differences between individual chips may be evened out, and the mechanical strength of the parallel chip may also be improved. Moreover, by parallel connecting thin chips which are limited in their capacities, a high capacity (over 100 nF) may be obtained, whereby the chips may be manufactured and embedded with an even thinner thickness.

As the electrical connection between the embedded chips and external circuits are achieved not by forming laser via holes (BVH's) and laminating but by perforating via holes mechanically and filling with conductive paste, the depth of a BVH can be made greater compared to its width, so that the defect of improper lamination may be resolved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a parallel chip embedded printed circuit board, the method comprising:
(a) forming a parallel chip by connecting in parallel a plurality of unit chips having electrodes or electrically connected members formed on the upper and lower surfaces thereof, using at least one conductive member;
(b) joining an electrode on one side of the parallel chip to a first board; and
(c) joining an electrode on the other side of the parallel chip to a second board.

2. A method of manufacturing a parallel chip embedded printed circuit board, the method comprising:
(d) forming a parallel chip by mounting a plurality of unit chips on at least one conductive member joined to a first board;
(e) stacking a third board, having at least one cavity perforated in correspondence with the position of the plurality of unit chips, onto the first board; and
(f) stacking a second board onto the third board, and electrically connecting the plurality of unit chips with external circuits.

3. The method of claim 1, wherein said operation (a) or said operation (b) further comprises forming a third board, having at least one cavity perforated in correspondence with the size of the parallel chip, and the method further comprises stacking the third board onto the first board to insert the parallel chip in the cavity, between said operation (b) and said operation (c).

4. The method according to either of claims 1 or 2, wherein the conductive member is any one or more of conductive pastes, conductive polymer films, conductive polymers, bidirectional conductive tapes, and conductive epoxys.

5. The method according to either of claims 2 or 3, wherein the third board is a copper clad laminate (CCL) with circuits formed thereon.

6. The method of claim 5, wherein the circuits formed on the third board are electrically connected with the parallel chip.

7. The method according to either of claims 2 or 3, wherein the cavity is perforated using a mechanical drill or a router.

8. The method of claim 1, wherein any one of said operations (a) to (c) further comprises forming one or more via holes in the portion of the first board or the second board where the parallel chip is joined and filling the via holes with conductive paste.

9. The method of claim 8, wherein the via holes are each formed in a position corresponding to the plurality of unit chips.

10. The method according to either of claims 8 or 9, further comprising electrically connecting the plurality of unit chips and the conductive paste by pressing the first board or the second board towards the parallel chip.

11. The method of claim 2, wherein any one of said operations (d) to (f) further comprises forming one or more via holes in the portion of the first board where the conductive member is joined or in the portion of the second board where the plurality of unit chips are joined and filling the via holes with conductive paste.

12. The method according to either of claims 1 or 2, further comprising adding at least one bumped copper foil having a plurality of protrusions from the exterior of the first board or the second board, and electrically connecting the plurality of unit chips and the bumped copper foil by pressing the bumped copper foil towards the plurality of unit chips, after the last operation.

13. The method of claim 12, wherein the plurality of protrusions are each formed in a position corresponding to the plurality of unit chips.

14. The method according to either of claims 1 or 2, wherein electrodes are formed on the left and right sides of the unit chip, and members electrically connected to the electrodes respectively are joined respectively to the upper and lower surfaces of the unit chip.

15. A printed circuit board with an embedded parallel chip, comprising:
a plurality of unit chips having electrodes or electrically connected members formed on the upper and lower surfaces thereof;
a first conductive member electrically connecting the upper surfaces of the plurality of unit chips; and
a second conductive member electrically connecting the lower surfaces of the plurality of unit chips.

16. The printed circuit board with an embedded parallel chip of claim 15, wherein the first conductive member is joined to a first board, and the second conductive member is joined to a second board.

17. The printed circuit board with an embedded parallel chip of claim 15, wherein a third board having a cavity perforated in correspondence with the size of the parallel chip is positioned between the first board and the second board, and the parallel chip is inserted into the cavity.

18. The printed circuit board with an embedded parallel chip of claim 17, wherein the third board is a copper clad laminate (CCL) with circuits formed thereon, and the circuits are electrically connected with the parallel chip.

19. The printed circuit board with an embedded parallel chip of claim 16, wherein one or more via holes are formed in the portion of the first board or the second board where the parallel chip is joined, and the via holes are filled with conductive paste.

20. The printed circuit board with an embedded parallel chip of claim 19, wherein the via holes are each formed in a position corresponding to the plurality of unit chips.

21. The printed circuit board with an embedded parallel chip of claim 16, wherein at least one bumped copper foil having a plurality of protrusions are joined to the exterior of the first board or the second board, and the plurality of protrusions are inserted into the first board or the second board.

22. The printed circuit board with an embedded parallel chip of claim 21, wherein the plurality of protrusions are each formed in a position corresponding to the plurality of unit chips.

23. The printed circuit board with an embedded parallel chip of claim 15, wherein the first conductive member and the second conductive member are any one or more of conductive polymer films, conductive polymers, bidirectional conductive tape, and conductive epoxy.
